(19) United States
(12) Patent Application Publication
(10) Pub. No.: US 2016/0115594 A1
(43) Pub. Date: Apr. 28, 2016

(54) SOURCE GAS SUPPLY APPARATUS AND FILM FORMING APPARATUS

(71) Applicant: TOKYO ELECTRON LIMITED, Tokyo (JP)

(72) Inventor: Masayuki MOROI, Nirasaki City (JP)

(21) Appl. No.: 14/887,697

(22) Filed: Oct. 20, 2015

(30) Foreign Application Priority Data
Oct. 28, 2014 (JP) 2014-219120

(51) Int. Cl. C23C 16/455; C23C 16/52; C23C 16/448

(52) U.S. Cl. CPC C23C 16/45561; C23C 16/4481; C23C 16/45544; C23C 16/52

(57) ABSTRACT

A source gas supply apparatus that supplies a carrier gas to a source container through a first supply path and that supplies a source gas to a consuming area of a source through a second supply path is provided. The source gas supply apparatus includes a flow path heater to heat a part between a discharge-side valve nearest to the source container among valves installed in the second supply path and the source container to a temperature equal to or higher than a sublimation temperature of the solid source, a container heater to heat the source container to a temperature equal to or higher than the sublimation temperature of the solid source, and a controller to output a control signal to cool the second supply path and the source container while the source container maintains a lower temperature than a temperature of the second supply path.

### CROSS-REFERENCE TO RELATED APPLICATION

This application claims the benefit of Japanese Patent Application No. 2014-219120, filed on Oct. 28, 2014, in the Japan Patent Office, the disclosure of which is incorporated herein in its entirety by reference.

### TECHNICAL FIELD

The present disclosure relates to a source gas supply apparatus for supplying a source gas including a source vaporized by supplying a carrier gas into a source container storing a solid source, to a consuming area of a source, and a film forming apparatus including the source supply apparatus.

### BACKGROUND

As a film forming process, which is a type of semiconductor manufacturing process, there are an Atomic Layer Deposition (ALD) process of alternately supplying a source gas and a reaction gas of, for example, oxidizing, nitriding or reducing the source gas, a Chemical Vapor Deposition (CVD) process of decomposing a source gas in a gas phase or reacting the source gas with a reaction gas, and so on. As the source gas used in this film forming process, a gas sublimated from the solid source may be used to increase a density of a crystal after the film formation and reduce an amount of impurities introduced to a wafer, and is used, for example, in forming a high dielectric film by ALD.

A source gas supply apparatus using a solid source is conventionally configured to connect an introduction pipe and a discharge pipe of a carrier gas, which is an inert gas, for example, a nitrogen gas to a ceiling portion of a source container surrounded by a heater to discharge a sublimated gas together with the carrier gas from the discharge pipe to be supplied into an interior of a process chamber.

In this regard, some consideration has been made to install a filter between a valve in the discharge pipe and the source container to avoid a scattered solid source from being introduced into the discharge pipe and attached onto the valve when the carrier gas is supplied to the source container, and to install a filter in the introduction pipe to prevent a scattered solid source from flowing backward to the introduction pipe. Meanwhile, from a viewpoint of constraints of apparatus structures or workability by operators, it has been considered that a source container, and pipes and valves connected to the source container are heated by separate mantle heaters, and the mantle heaters are turned on/off by a common switch at one time.

However, when both of the mantle heaters are turned off, since a heat capacity of the source container is greater than a heat capacity of the pipe or the valve, the pipes and the valves are cooled earlier than the source container. Thus, when a gas of a high temperature equivalent to the temperature of the gas phase of the source container stays in a region between the filter and valve in the discharge path, since a concentration of the source in the gas is high, an amount of re-solidification of the solid source is increased when the gas is cooled. Therefore, there is concern that the solid source is stuck in the valve, which results in increasing maintenance frequency.

### SUMMARY

The present disclosure provides a source gas supply apparatus and a film forming apparatus including the source gas supply apparatus, capable of eliminating the occurrence of trouble in a valve by suppressing re-solidification of a solid source when supplying a carrier gas to a source container storing a solid source to supply a source gas including a vaporized-source to a consuming area of a source.

According to an embodiment of the present disclosure, there is provided a source gas supply apparatus that supplies a carrier gas, which is an inert gas, to a source container storing a solid source through a first supply path and that supplies a source gas including a vaporized source to a consuming area of a source through a second supply path. The source gas supply apparatus includes a flow path heater configured to heat a part between a discharge-side valve nearest to the source container among valves installed in the second supply path and the source container to a temperature equal to or higher than a sublimation temperature of the solid source, a container heater configured to heat the source container to a temperature equal to or higher than the sublimation temperature of the solid source, and a controller configured to output a control signal to cool the second supply path and the source container while an interior of the source container maintains a lower temperature than a temperature of a part ranging from the source container to the discharge-side valve in the second supply path when stopping heating of the flow path heater and the container heater.

According to another embodiment of the present disclosure, there is provided a source gas supply apparatus that supplies a carrier gas, which is an inert gas, to a source container storing a solid source through a first supply path and that supplies a source gas including a vaporized source to a consuming area of a source through a second supply path. The source gas supply apparatus includes a heater configured to heat a part between an discharge-side valve nearest to the source container among valves installed in the second supply path and the source container and the source container to a temperature equal to or higher than a sublimation temperature of the solid source, and a source recovering member installed in an interior of the source container and have a cooling rate faster than a cooling rate of gas phase of the interior of the source container when stopping heating of the heater.

According to another embodiment of the present disclosure, there is provided a film forming apparatus including the source gas supply apparatus mentioned above, a processing container including a mounting table mounting a substrate thereon, and configured to receive a source gas including a vaporized source supplied through a second supply path to the processing container, and an exhaust mechanism configure to exhaust an atmosphere of an interior of the processing container.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an overall block diagram illustrating a film forming apparatus to which a source gas supply apparatus according to a first embodiment of the present disclosure applied.

FIG. 2 is a block diagram of a controller installed in the film forming apparatus.

FIG. 3 is a flowchart illustrating on/off processes of heaters.

FIG. 4 is a characteristic diagram illustrating a change in temperatures of a flow path heater and a container heater.

FIG. 5 is a characteristic diagram illustrating a vapor pressure curve of WCl₆.

FIG. 6 is a block diagram of a controller installed in a film forming apparatus according to another example of the first embodiment.

FIG. 7 is a flowchart illustrating on/off processes of heaters in another example of the first embodiment.

FIG. 8 is a partially cutaway perspective view illustrating a source gas supply apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

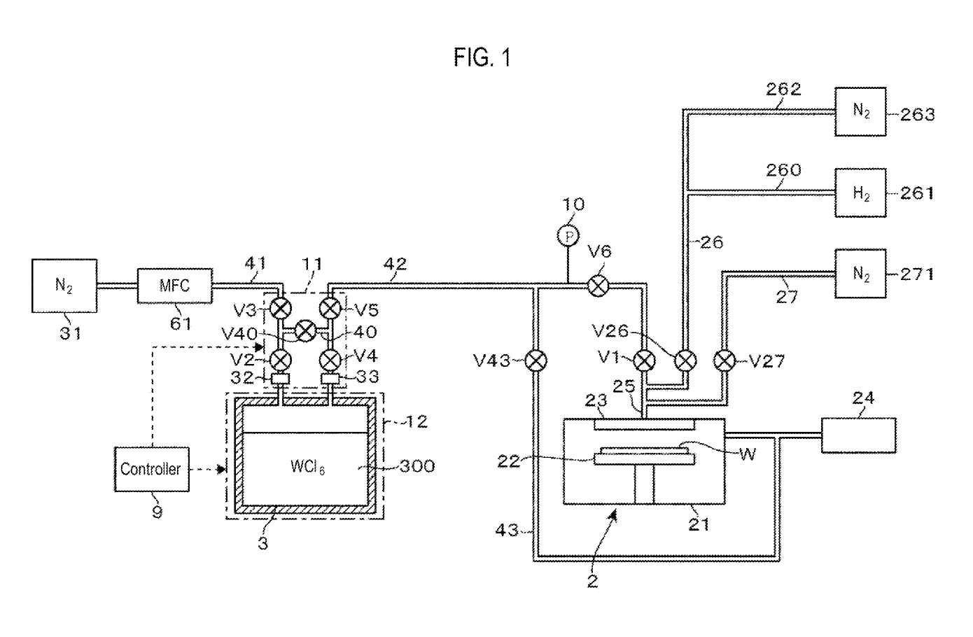

A configuration example of applying a source gas supply apparatus according to an embodiment of the present disclosure to a film forming apparatus will be described. As illustrated in FIG. 1, the film forming apparatus includes a film forming processing part 2, which is a consuming area of a source gas, for performing film forming processing with respect to a wafer W, i.e., a substrate by ALD, and a source gas supply part, which is the source gas supply apparatus, for supplying a source gas to the film forming processing part 2.

The film forming processing part 2 includes, for example, a mounting table 22 configured to horizontally hold the wafer W in a vacuum container 21, which is a vacuum chamber as a processing container, and having a heater (not shown), and a gas introduction part 23 (specifically, a gas shower head) to introduce the source gas and so forth into an interior of the vacuum container 21. The interior of the vacuum container 21 is vacuum-exhausted by a vacuum exhaust part 24 constituted with a vacuum pump and so forth, and the source gas is introduced into the interior of the vacuum container 21 from the source gas supply part to perform the film forming on a surface of the heated wafer W.

For example, when forming tungsten (W) film, WCl₆, which is a powder (solid) at room temperature, is used as a source, and hydrogen (H₂) gas is used as a reaction gas (a reducing gas) which reacts with the source. Thus, a gas supply path 25 is connected to the gas introduction part 23. At the gas supply path 25, a source gas supply path 42 for supplying the source gas including WCl₆ to be described later, a reaction gas supply path 26 for supplying the reaction gas reacting with the source gas, and a purge gas supply path 27 for supplying a purge gas are joined through valves V1, V26, and V27, respectively. The other end side of the reaction gas supply path 26 branches off to a gas supply path 260 connected to a reaction gas supply source 261 and a gas supply path 262 connected to, for example, a nitrogen gas (N₂) supply source 263 for supplying an inert gas. Further, the other end side of the purge gas supply path 27 is connected to, for example, a N₂ gas supply source 271 for supplying the purge gas.

The source gas supply part of the embodiment includes a source container 3 storing WCl₆, which is the source and solid in room temperature and made of, for example, stainless steel. A downstream end portion of a carrier gas supply path 41, which becomes a first supply path to introduce a carrier gas into the source container 3, and an upstream end portion of the source gas supply path 42, which becomes a second supply path to discharge the source gas from the source container 3, are connected to an upper side of a solid source 300 in the source container 3. Each of the carrier gas supply path 41 and the source gas supply path 42 is made of a pipe passing through a ceiling plate of the source container 3 and extended upward from the ceiling.

In a front end of the carrier gas supply path 41, a carrier gas supply source 31, which is a N₂ gas supply source, is installed. In the carrier gas supply path 41, a mass flow controller (MFC) 61 is installed for controlling a flow rate of the carrier gas in the upstream side to a setting value. In the pipe extended upward from the ceiling in the carrier gas supply path 41, valves V3 and V2, and a filter 32 are installed in this order from the upstream side.

Meanwhile, in the source gas supply path 42, a filter 33, valves V4 and V5, a pressure gauge 10 and a valve V6 are installed in this order from the upstream side of the pipe extended upward from the ceiling. From the upstream side of the valve V6, a branch path 43 where the valve V43 is provided is branched, and connected to the aforementioned vacuum exhaust part 24 while bypassing the vacuum container 21. A part between the valves V2 and V3 in the carrier gas supply path 41 and a part between the valves V4 and V5 in the source gas supply path 42 are connected through a bypass path 40 including a valve V40. Further, the bypass path 40 where the valve V40 is provided includes a pipe and a valve for cycle purge and is used to remove the gas remaining in the pipe by closing the valves V2 and V4 prior to connection to the source container 3, opening the valves V3, V5 and V40, and making, for example, nitrogen gas flow into the carrier gas supply path 41, the bypass path 40, and the source gas supply path 42.

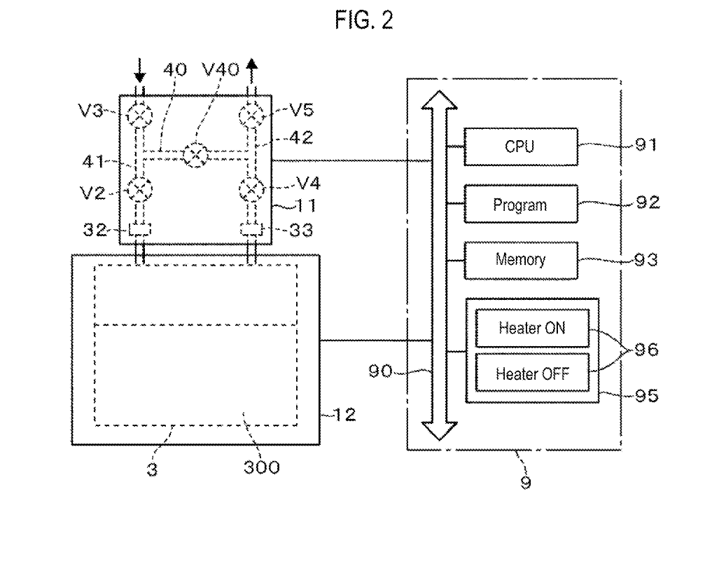

Next, heaters for heating the source container 3, and portions of the source container 3-side source gas supply path 42 and the carrier gas supply path 41 will be described with reference to FIG. 2. A portion downstream of the valve V3 up to the filter 32 in the carrier gas supply path 41, a portion upstream of the valve V5 up to the filter 33 in the source gas supply path 42, and the bypass path 40 are surrounded by a jacket-shaped mantle heater including a resistance heating element, which constitutes a flow path heater 11. The flow path heater 11 is configured to regulate a temperature of the flow path surrounded by the flow path heater 11 by adjusting electric power supplied from a power supply (not shown), whereby the temperature of the flow path heater 11 may be set to 160 degrees C., which is a temperature higher than that of a container heater 12, so as to be not less than the temperature of a container heater 12. Further, a portion, which is not surrounded by the flow path heater 11 in the source gas supply part 42, is covered with, for example, a tape heater (not shown). An area, which is covered with the tape heater in the source gas supply part 42, is heated to a temperature in which the source gas is not deposited.

The source container 3 is surrounded by a jacket-shaped mantle heater including a resistance heating element, which constitutes the container heater 12. The container heater 12 is configured to regulate the temperature of the source container 3 surrounded by the container heater 12 by adjusting electric power supplied from a power supply (not shown). The temperature of the container heater 12 is set within a range in which the solid source 300 is sublimated and the WCl₆ is not decomposed, for example, 150 degrees C.

Further, as illustrated in the FIG. 2, the flow path heater 11 and the container heater 12 are connected to a controller 9. The controller 9 includes, for example, a program 92 formed of step (order) groups associated with on/off control of a heater which is connected to a bus 90 and to be described later, a memory 93, and a CPU 91 for executing the program. In the controller 9, a manipulation panel 95 is installed. A main switch 96 which is a common on/off switch part of the flow path heater 11 and the container heater 12 is operated by the manipulation panel 95. By operating the manipulation panel 95, when the main switch 96 is turned on, a control of turning on each of the flow path heater 11 and the container heater 12 starts, and when the main switch 96 is turned off, a control of turning off each of the flow path heater 11 and the container heater 12 starts.

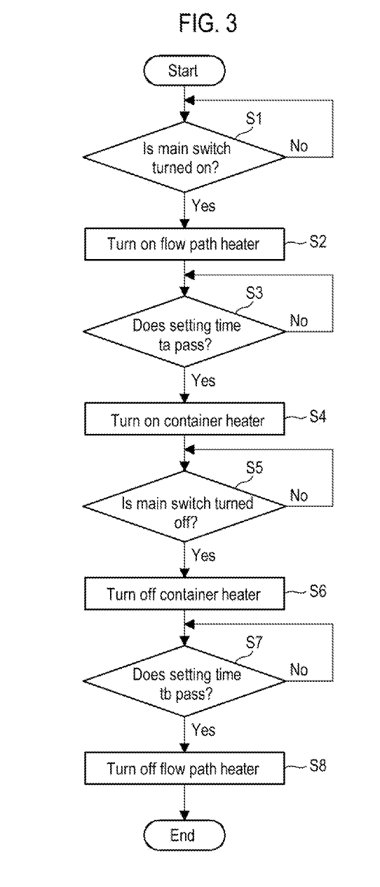

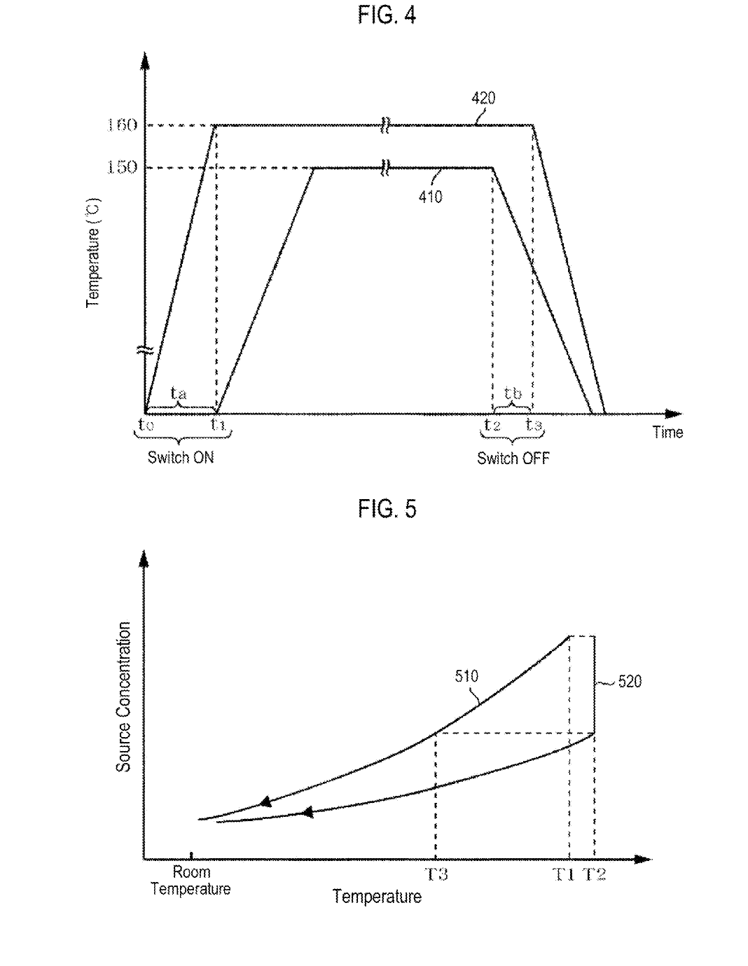

Next, an operation of the aforementioned embodiment will be described with reference to a flowchart illustrated in FIG. 3 and temperature profiles in the container heater 12 and the flow path heater 11 illustrated in FIG. 4. In FIG. 4, a solid line 410 is a temperature profile at the interior of the source container 3, and a solid line 420 is a temperature profile at a heating area heated by the flow path heater 11. Hereinafter, in the present disclosure, the heating area to be heated by the flow path heater 11 will refer to as a flow path-side area.

When starting an operation of the film forming apparatus, first, the main switch 96 is turned on at time t0 by the manipulation panel 95, then the process proceeds to step S2 via step S1, to start power feeding to the flow path heater 11 (the flow path heater 11 is turned on.). Then, heating of the flow path-side area is started. Until a predetermined time ta passes after the main switch 96 is turned on, the container heater 12 maintains in a turn-off state. However, at a time t1 that the predetermined time ta passes, it is determined as “Yes” in step S3 and the process proceeds to step S4 to start power feeding to the container heater 12 (the switch of the container heater 12 is turned on). Then, heating of the source container 3 is started. At this time, since the flow path-side area is heated from time t0 to time t1, the flow path-side area becomes a higher temperature than the interior of the source container 3, specifically, 160 degrees C.

When the container heater 12 is turned on, a temperature of a certain portion such as a wall surface of the source container 3 or the like is increased partially, so that there is concern that a part of the source is sublimated and flows to the flow path. By turning on the container heater 12 after the temperature of the flow path-side area becomes 160 degrees C., even if the source is heated partially and rapidly, and then sublimated, deposition of the source gas in the flow path-side area can be suppressed definitely. When the container heater 12 is turned on, it is not limited to increase the temperature of the flow path-side area up to a setting temperature. However, from a viewpoint that deposition of the source in the flow path-side area is suppressed definitely after the container heater 12 is turned on, it is preferable in some embodiments to turn on the container heater 12 after the temperature of the flow path-side area becomes equal to or higher than a sublimation temperature. A proper temperature is measured by operating the source gas supply apparatus beforehand, and then the setting time ta is determined based on the measured temperature.

Moreover, since the source container 3 has a heat capacity greater than those of the pipes constituting the carrier gas supply path 41 and the source gas supply path 42, a temperature rising rate of the flow path-side area is faster than a temperature rising rate of the interior of the source container 3. For this reason, during the heating of the flow path heater 11 and the container heater 12 up to the setting temperature, a temperature of the flow path-side area is always higher than a temperature of the interior of the source container 3. After that, the temperature of the flow path-side area reaches up to 160 degrees C., and the temperature of the interior of the source container 3 reaches up to 150 degrees C. When the source container 3 is heated by turning on the container heater 12 and a temperature thereof reaches up to a sublimation temperature of WCl₆, the source concentration in an atmosphere of the source container 3 becomes a saturated concentration.

After the source container 3 is heated, the wafer W is loaded on the mounting table 22 in the film forming processing part 2. And then the interior of the vacuum container 21 is vacuum-exhausted and the wafer W is heated. In this way, after preparation for performing film formation is completed, the film forming process is performed by, for example, ALD. First, the carrier gas is supplied from the carrier gas supply path 41 to the source container 3 by opening the valves V1, V2, V3, V4, V5 and V6 of the source container 3, the source gas is discharged into the source gas supply path 42 with the carrier gas to supply the resource gas and the carrier gas to the vacuum container 21 for, e.g., one second, and then the valve V1 is closed, thereby adsorbing WCl₆ on a surface of the wafer W.

Next, a purge gas (N₂ gas) is supplied to the vacuum container 21 to purge the interior of the vacuum container 21. Next, a valve V26 is opened to supply a reaction gas (H₂ gas) to the vacuum container 21, and the valve V26 is closed. WCl₆ adsorbed on the wafer W is reduced by H₂, thereby forming a W film of one atomic layer. After that, the purge gas is supplied to the vacuum container 21 to purge the interior of the vacuum container 21. In this manner, a cycle of supplying the source gas including WCl₆, the purge gas, the reaction gas, and the purge gas in this order to the interior of the vacuum container 21 is performed a plurality of times by on/off control of the valves V1, V26 and V27 to thereby perform W film formation having a predetermined thickness. After the film forming process is completed, the wafer W is unloaded from the film forming apparatus.

After a series of the film forming processes is completed, the operation of the film forming apparatus is stopped. At time t2 illustrated in the FIG. 4, when the main switch 96 is turned off by the manipulation panel 95, it is determined as “Yes” in step S5, and then the process proceeds to step S6 to turn off the container heater 12. After that, at time t3 when a setting time tb passes, it is determined as “Yes” in step S7, and then the process proceeds to the step S8 to turn off the flow path heater 11. At time t3, the temperature of the source container 3 decreases to, for example, 120 degrees C. Then, after the flow path-side area and the interior of the source container 3 are cooled down to room temperature, the operation of the film forming apparatus is stopped. When turning off the flow path heater 11, the temperature of the source container 3 is the temperature that, after turning off the flow path heater 11, the deposition of the source in the flow path-side area is sufficiently suppressed. The source gas is driven in advance and a proper temperature is measured, thereby determining a setting time tb based on the measured temperature.

As described above, since the heat capacity of the source container 3 is greater than that of the flow path-side area, it is hard to be cooled. For that reason, stop of power feeding to the container heater 12 is performed prior to stop of power feeding to the flow path heater 11, so that the temperature of the flow path-side area becomes higher than the temperature of the interior of the source container 3 during a period of time until the source container 3 is cooled down to room temperature.

FIG. 5 is a diagram schematically illustrating a relationship between temperature (horizontal axis) and source concentration (vertical axis) with respect to the interior of the source container 3 and the flow path-side area. T1, T2, and T3 correspond to a heating temperature of the source container 3, a heating temperature of the flow path-side area, and a temperature of the interior of the source container 3 at a time when the flow path heater 11 is turned off, respectively. In the interior of the source container 3, the temperature is decreased from the temperature T1 by turning off the container heater 12, and the source concentration of the interior of the source container 3 is getting lowered along the saturation vapor pressure curve as illustrated as a solid line 510.

On the contrary, in the flow path-side area, when the flow path heater 11 is turned off, the concentration of the source is lowered to a concentration equivalent to a saturated concentration corresponding to the temperature T3 as illustrated in a solid line 520. After that, the source concentration is lowered with the decrease in the saturated concentration of the interior of the source container 3 accompanying the temperature decrease.

On the other hand, when the flow path heater 11 and the container heater 12 are simultaneously turned off, as described in the background, since the heat capacity of the source container 3 is greater than a heat capacity of the flow path-side area, the temperature of the flow path-side area is decreased earlier. In the source container 3, the internal solid source 300 is sublimated by heating, so that the source gas becomes the saturated concentration. For that reason, when the temperature of the flow path area drops, the source gas introduced in the flow path-side area from the source container 3 is cooled, so that the source is deposited.

According to the aforementioned embodiment, in the apparatus of extracting the source sublimated from the solid source by heating the source container 3 and each of the flow paths where the carrier gas flows in and out at a time that the carrier gas is introduced into the interior of the source container 3 storing WCl₆, the apparatus is controlled such that the container heater 12 is turned off earlier than the flow path heater 11 when stopping the heating, and then the flow path heater 11 is turned off. For that reason, the temperature of the flow path-side area connected to the source container 3 is cooled down to room temperature while maintaining the temperature higher than the temperature of the interior of the source container 3. Consequently, as described above in detail, re-solidification of the WCl₆ in the flow path-side area is suppressed, and troubles in the valves V2 and V4 may not occur.

Moreover, in the embodiment described above, when the main switch 96 is turned on, the container heater 12 is turned on after the setting time passes. In other words, after the temperature of the flow path-side area is sufficiently increased, the container heater 12 is turned on, so that the temperature of the flow side path area is not lower than the temperature of the source container. However, for example, if the heat capacity of the flow path-side area is smaller than the heat capacity of the source container 3, since a temperature rising rate is getting faster in the flow path-side area compared to the source container 3, it may be configured such that the flow path heater 11 and the container heater 12 are turned on simultaneously. In this case, since the flow path-side area maintains a higher temperature than the interior of the source container 3 after the flow path heater 11 and the container heater 12 are simultaneously turned on by turning on the main switch 96, deposition of the source in the flow path-side area can be suppressed.

### Another Example of the First Embodiment

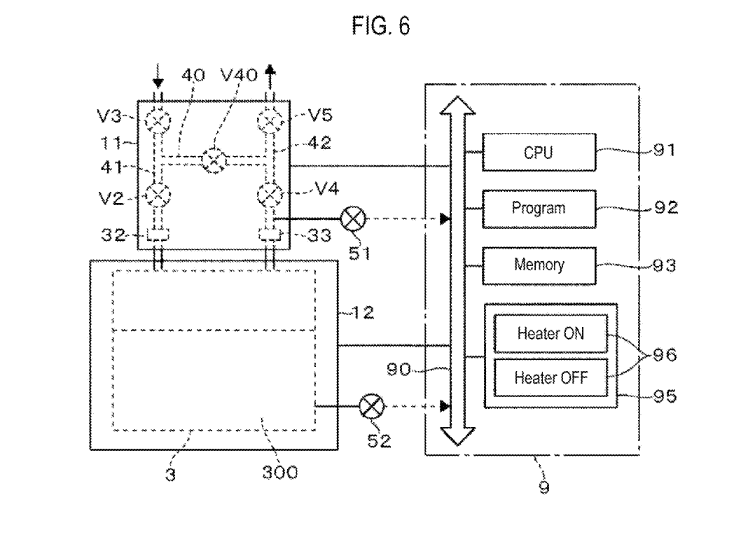

In the first embodiment, in order to adjust the heating temperatures of the flow path heater 11 and the container heater 12 to 160 degrees C. and 150 degrees C., which are setting temperatures, respectively, temperature detection is performed in each of the flow path heater 11 and the container heater 12. The detected values may be used to control the turn-on timing of the container heater 12 and the turn-off timing of the flow path heater 11. In this case, as illustrated in the FIG. 6, it is configured such that temperature detection values detected from each of a flow path temperature detector 51 for detecting the temperature of the flow path-side area and a container temperature detector 52 for detecting the temperature of the interior of the source container 3 are inputted to the controller 9.

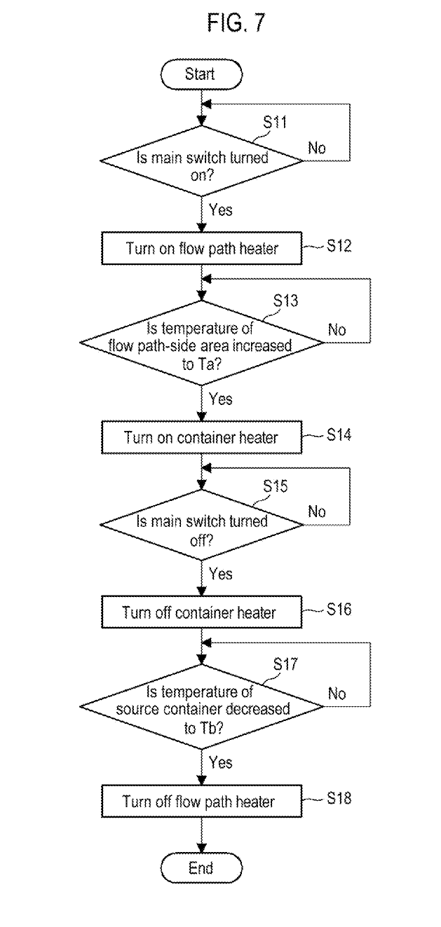

In those examples, on/off operations of the flow path heater 11 and the container heater 12 will be described with reference to a flowchart of FIG. 7. Similar to the first embodiment, when the main switch 96 is turned on (Step S11), the flow path heater 11 is turned on (Step S12). Next, in Step S13, it is determined whether the temperature detected from the flow path temperature detector 51 is increased up to a temperature Ta at which saturated gas concentration of the flow path-side area in the flow path becomes sufficiently high, for example, 160 degrees C. After the temperature rises to the temperature Ta, the process proceeds to step S14 to turn on the container heater 12, and heating of the source container 3 is started.

After that, the film forming process is ended. Then, when the main switch 96 is turned off by operating the manipulation panel 95, the process proceeds to step S16 through step S15 to turn off the container heater 12. Next, in step S17, the process waits until the detected temperature of the container temperature detector 52 is lowered to a temperature Tb, for example, 120 degrees C., at which the deposition is suppressed when the concentration of the saturated gas in the source container 3 is sufficiently lowered, so that the gas in the interior of the source container 3 is introduced to the flow path-side area. Then, when the temperature of the container temperature detector 52 is decreased to the temperature Tb, the process proceeds to step S18 to turn off the flow path heater 11. In this configuration, the temperature of the flow path-side area is decreased while maintaining a higher temperature than the temperature of the interior of the source container 3, whereby the same effect as the first embodiment can be obtained.

Moreover, if the main switch 96 is turned off, it may be configured such that the flow path-side area has a heat capacity greater than that of the interior of the source container 3, and the flow path heater 11 and the container heater 12 are simultaneously turned off.

In the aforementioned embodiment, although it is described that a portion of the carrier gas supply path 41, which is a side toward the source container 3, and a portion of the source gas supply path 42, which is a side toward the source container 3, are heated by the flow path heater 11, the flow path heater 11 may be divided into a heater for heating the carrier gas supply path 41 and a heater for heating the source gas supply path 42. In this case, turn-off timing only for the heater to heat the source gas supply path 42 may be delayed as already described with respect to the turn-off timing of the container heater 12. However, since the source gas flows backward from the source container 3 to the carrier gas supply path 41 due to diffusion of the source gas, it is preferable in some embodiments to control the carrier gas supply path 41 to have a higher temperature than the source container 3.

### Second Embodiment

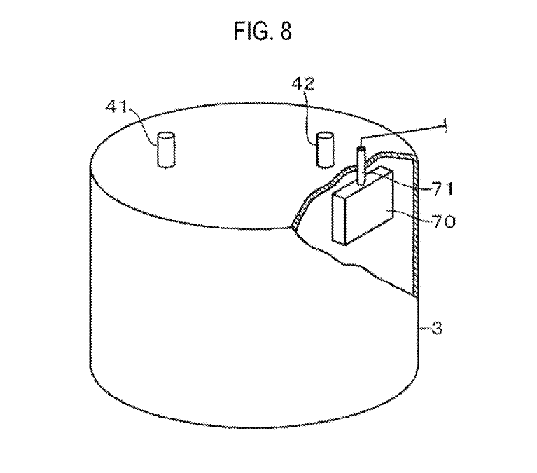

In the present disclosure, as a method for suppressing deposition of the source in the flow path-side area, for example, a sequence for simultaneously stopping power feeding to the flow path heater 11 and the container heater 12 and a method illustrated in FIG. 8 may be adopted. In FIG. 8, a plate-shaped source recovering member 70 is installed between a lower side of the opening of the source gas supply path 42 and an inner peripheral surface of the source container 3 with being hung by providing a support member 71 from a ceiling portion of the source container 3, and is set such that the plate plane thereof faces a central portion of the source container 3. The source recovering member 70 includes Peltier elements installed therein, and plate-shaped units, each having one plane and the other plane formed as a cooling plane and a heating plane, respectively, are bonded to make the heating planes face each other, so that the plate plane of the source recovering member 70 becomes a cooling plane.

In the embodiment, cooling of the source recovering member 70 is started at a step for turning off the flow path heater 11 and the container heater 12 in order to stop running the film forming apparatus. In this case, even if the flow path heater 11 and the container heater 12 are turned off simultaneously, since the source recovering member 70 is cooled at a rate faster than the cooling rate of gas phase in the source container 3, the source gas to be introduced from the source container 3 to the source gas supply path 42 is cooled and deposited by the source recovering member 70. As a result, the gas concentration of the source gas introduced to the source gas supply path 42 decreases, and deposition of the source gas in the source gas supply path 42 is suppressed.

Also, in the present disclosure, the second embodiment and the first embodiment may be used together.

The present disclosure is related to the apparatus of supplying a source sublimated from a solid source by heating the source container and each of the flow paths where the carrier gas flows in and out, to the consuming area at a time that the carrier gas is introduced into the interior of the source container storing the solid source, and the film forming apparatus including this apparatus. When stopping the heating, the temperature of the interior of the source container is controlled to be lower than the temperature of the vicinity of the source container in the flow path where the source gas is discharged from the source container. For that reason, the source concentration of the gas staying in the flow path where the source gas is discharged is lowered, so that re-solidification of the solid source is suppressed, and the solid source is suppressed from being stuck in the valves, which results in decreasing the maintenance frequency.

According to another aspect of the present disclosure, when heating by the container heater is stopped, since the source recovering member having a cooling rate faster than a cooling rate of gas phase in the source container is installed in the source container, re-solidification occurs on surfaces of the source recovering member, so that the source concentration of the gas staying in the flow path where the source gas is discharged is lowered, which results in the same effect.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A source gas supply apparatus that supplies a carrier gas, which is an inert gas, to a source container storing a solid source through a first supply path and that supplies a source gas including a vaporized source to a consuming area of a source through a second supply path, the source gas supply apparatus comprising:
a flow path heater configured to heat a part between a discharge-side valve nearest to the source container among valves installed in the second supply path and the source container to a temperature equal to or higher than a sublimation temperature of the solid source;
a container heater configured to heat the source container to a temperature equal to or higher than the sublimation temperature of the solid source; and
a controller configured to output a control signal to cool the second supply path and the source container while an interior of the source container maintains a lower temperature than a temperature of a part ranging from the source container to the discharge-side valve in the second supply path when stopping heating of the flow path heater and the container heater.

2. The source gas supply apparatus of claim 1, further comprising an off switch part installed to turn off the flow path heater and the container heater at one time, and configured to send an off instruction to the controller by a manipulation thereof.

3. The source gas supply apparatus of claim 1, wherein a filter is installed between the source container and the discharge-side valve in the second supply path to remove particles.

4. The source gas supply apparatus of claim 1, wherein the flow path heater is configured to heat a part between an introduction-side valve nearest valve to the source container among valves installed in the first supply path and the source container to the temperature equal to or higher than the sublimation temperature of the solid source, and
wherein the interior of the source container maintains in a lower temperature than a temperature of a part ranging from the source container to the introduction-side valve when stopping heating of the flow path heater and the container heater.

5. The source gas supply apparatus of claim 1, wherein the controller is configured to output a control signal to stop power feeding to the container heater after receiving an off instruction of a heater and then stop power feeding to the flow path heater after a predetermined time passes.

6. The source gas supply apparatus of claim 1, further comprising a temperature detector detecting a temperature of an area to be heated by the container heater,
wherein the controller is configured to output a control signal to stop power feeding to the container heater after receiving an off instruction of a heater and then stop power feeding to the flow path heater after a temperature detected by the temperature detector becomes equal to or less than a setting temperature.

7. The source gas supply apparatus of claim 1, wherein the controller is configured to output a control signal such that a part ranging from the source container to the discharge-side valve stays at a higher temperature than a temperature of an interior of the source container when starting heating of each of areas to be heated by the flow path heater and the container heater.

8. A source gas supply apparatus of supplying a carrier gas, which is an inert gas, to a source container storing a solid source through a first supply path and supply a source gas including a vaporized source to a consuming area of a source through a second supply path, the source gas supply apparatus comprising:
a heater configured to heat a part between an discharge-side valve nearest to the source container among valves installed in the second supply path and the source container and the source container to a temperature equal to or higher than a sublimation temperature of the solid source; and
a source recovering member installed in an interior of the source container and having a cooling rate faster than a cooling rate of gas phase of the interior of the source container when stopping heating of the heater.

9. The source gas supply apparatus of claim 8, wherein the heater includes:
a flow path heater configured to heat the portion including the part between the discharge-side valve nearest to the source container among the valves installed in the second supply path and the source container to the temperature equal to or higher than the sublimation temperature of the solid source; and
a container heater configured to heat the source container to the temperature equal to or higher than the sublimation temperature of the solid source.

10. A film forming apparatus comprising:
a source gas supply apparatus of claim 1;
a processing container including a mounting table mounting a substrate thereon, and configured to receive a source gas including a vaporized source supplied through a second supply path to the processing container; and
an exhaust mechanism configure to exhaust an atmosphere of an interior of the processing container.
